(19) United States
(12) Patent Application Publication
(10) Pub. No.: US 2009/0260681 A1
(43) Pub. Date: Oct. 22, 2009

(54) SOLAR CELL AND METHOD FOR MANUFACTURING THE SAME

(75) Inventors: Ju-Hwan YUN, Seoul (KR); Jong-Hwan Kim, Seoul (KR); Bum-Sung Kim, Seoul (KR); Ji-Hoon Ko, Seoul (KR)

Correspondence Address: BIRCH STEWART KOLASCH & BIRCH, PO BOX 747, FALLS CHURCH, VA, 22040-0747, US

(73) Assignee: LG Electronics Inc., Seoul (KR)

(21) Appl. No.: 12/391,739

(22) Filed: Feb. 24, 2009

(30) Foreign Application Priority Data
Feb. 25, 2008 (KR) 10-2008-0016900

(51) Int. Cl. H01L 31/0232; H01L 21/28

(52) U.S. Cl. 136/256; 438/72; 257/E21.158; 257/E31.127

(57) ABSTRACT

The present invention relates to a solar cell and a method for manufacturing the same. More specifically, the present invention provides a silicon solar cell capable of minimizing defects and recombination of electrons-holes by removing a damaged layer formed by a laser edge isolation process to isolate a silicon substrate and covering a protective layer on a surface thereof and a method for manufacturing the same.

### BACKGROUND OF THE INVENTION

This application claims priority to Korean Patent Application No. 10-2008-0016900, filed on Feb. 25, 2008, in the Korean Intellectual Property Office, the entire contents of which are hereby incorporated by reference.

1. Field of the Invention

The present invention relates to a solar cell and a method for manufacturing the same, and more specifically, to a silicon solar cell capable of minimizing defects and recombination of electrons-holes by removing a damaged layer formed by a laser edge isolation process to isolate a silicon substrate and covering a protective layer on a surface thereof and a method for manufacturing the same.

2. Description of the Related Art

Owing to problems of environmental pollution and an exhaustion of resources, etc., there is an urgent demand for the development of pollution free clean energy. Therefore, a solar cell has attracted a great deal of interest, together with nuclear energy and wind power. A solar cell based on a silicon (Si) single crystal and polycrystalline substrate has currently developed and commercialized, and studies into an amorphous silicon thin film solar cell and a thin film type compound semiconductor solar cell have been actively progressed in order to manufacture a cheaper solar cell through reduction in use of raw materials.

The solar cell is a device that converts light energy into electric energy using a photovoltaic effect. Such a solar cell is classified into a silicon solar cell, a thin film solar cell, a dye-sensitized solar cell, an organic polymer solar sell, and the like according to constituent materials. Such a solar cell is independently used as a main power supply for an electronic clock, a radio, an unmanned lighthouse, an artificial satellite, a rocket, and the like and as an auxiliary power supply by being connected to a commercial alternating power supply. Recently, there is much growing interest into solar cells due to an increased need of alternate energy.

### SUMMARY OF THE INVENTION

An object of the present invention is to provide a silicon solar cell capable of minimizing recombination of electrons-holes and defects at a surface-protected portion by protecting a surface subjected to a laser edge isolation process to isolate a front surface and a rear surface of a substrate.

Another object of the present invention is to provide a method for manufacturing a silicon solar cell capable of minimizing recombination of electrons-holes and defects at a surface-protected portion by performing a laser edge isolation process and covering a surface subjected to the edge isolation process with a protective layer, after forming a p-n junction.

### [Technical Solution]

To achieve the above objects, according to one aspect of the present invention, there is provided a solar cell comprising: a first conductive type semiconductor substrate; a second conductive type semiconductor layer that is formed on the substrate and has a conductive type opposite to the first conductive type; at least one groove that penetrates through the second conductive type semiconductor layer and reaches a predetermined depth of the first conductive type semiconductor substrate; a protective layer formed on the groove; a first electrode that electrically contacts the second conductive type semiconductor layer; and a second electrode that is formed on the first conductive type semiconductor substrate.

In the present invention, the groove may be formed at an edge of the solar cell. And, in the present invention, the groove may be an edge isolation region to isolate front and rear surfaces of the first conductive type semiconductor substrate.

In the present invention, the rear surface of the substrate may be further provided with a rear electric field layer beside the second electrode.

In the present invention, the surface of the first conductive type semiconductor substrate may have an unevenness structure.

In the present invention, the second conductive type semiconductor layer may be formed on the front surface of the semiconductor substrate and the second electrode is formed on the rear surface of the semiconductor substrate. And, in the present invention, the second conductive type semiconductor layer and the second electrode may be formed on the rear surface of the semiconductor substrate.

In the present invention, an anti-reflective layer may be formed on the second conductive type semiconductor layer. The anti-reflective layer may be made of one or more material selected from the group consisting of silicon nitride (SiNₓ), silicon oxide (SiO₂), and intrinsic amorphous silicon. The thickness of the anti-reflective layer may be 10 nm to 900 nm. And, the anti-reflective layer may be formed of two layers or more.

In the present invention, the anti-reflective layer may be made of the same material as the protective layer. And, the anti-reflective layer may be connected to the protective layer.

According to another aspect of the present invention, there is provided a method of manufacturing a solar cell, comprising: forming a first conductive type semiconductor layer; forming a second conductive type semiconductor layer having a conductive type opposite to the first conductive type on a first conductive type semiconductor substrate; performing edge isolation to isolate front and rear surfaces of the first conductive type semiconductor substrate; removing a damaged layer formed by the edge isolation; burying a groove formed by removing the damaged layer and forming an anti-reflective layer applied on the second conductive type semiconductor layer; and forming a first electrode that contacts at least a portion of the second conductive type semiconductor layer and the anti-reflective layer, and a second electrode that contacts at least a portion of the rear surface of the substrate.

Preferably, the method the present invention further comprises the step of forming the rear electric field layer on the rear surface of the substrate before, during, or after forming the first and second electrodes.

In the present invention, the step of forming the second conductive type semiconductor layer is performed by doping a second conductive type semiconductor impurity having a conductive type opposite to the first conductive type on the first conductive type semiconductor substrate.

Preferably, the method the present invention further comprises the step of texturing the surface of the first conductive type semiconductor substrate, prior to forming the first and second electrodes.

Preferably, the method the present invention further comprises the step of removing an insulating layer generated in the process of forming the second conductive type semiconductor layer, prior to forming the anti-reflective layer.

In the present invention, the edge isolation may include any one of a laser edge isolation method, a plasma etching method, and an etchant etching method.

In the present invention, the anti-reflective layer may be made of one or more material selected from the group consisting of silicon nitride (SiNₓ), silicon oxide (SiO₂), and intrinsic amorphous silicon. And, the thickness of the anti-reflective layer may be 10 nm to 900 nm. In addition, the anti-reflective layer may be formed of two layers or more.

In the present invention, the step of forming the first electrode may include forming an electrode on the anti-reflective layer, performing heat treatment thereon, and contacting it on the second conductive type semiconductor layer.

According to the present invention, the recombination of electrons-holes and the defects at the surface-protected portion are minimized by protecting the surface subjected to the edge isolation process to isolate the front surface and the rear surface of the substrate, making it possible to improve the efficiency of the solar cell.

Also, according to the present invention, the surface subjected to the edge isolation process is protected by a process that makes little difference from a method for manufacturing a silicon solar cell of the related art, making it possible to improve the efficiency of the solar cell without causing a significant increase in the sophistication of the process and an increase of the manufacturing costs.

### BRIEF DESCRIPTION OF THE DRAWINGS

The above and other objects, features and advantages of the present invention will become apparent from the following description of preferred embodiments given in conjunction with the accompanying drawings, in which:

FIG. 1 is a cross-sectional view schematically showing a basic structure of a silicon solar cell according to one embodiment of the present invention; and

FIGS. 2 to 8 are process diagrams for explaining manufacturing processes of a silicon solar cell according to one embodiment of the present invention.

### DETAILED DESCRIPTION OF THE INVENTION

Hereinafter, terms used for components of the present invention are not limited to the above-mentioned terms but those skilled in the art can use easily replaceable terms.

In a solar cell according to one embodiment of the present invention, a first conductive type semiconductor substrate is not particularly limited but preferably, may be a p-type silicon substrate or an n-type silicon substrate.

Further, a second conductive type semiconductor layer may be called a second conductive type emitter layer. Meanwhile, since the second conductive type semiconductor layer has a conductive type opposite to the first conductive type semiconductor substrate, the second conductive type semiconductor layer is an n-type semiconductor layer or an n-type emitter layer in the case of the p-type silicon substrate and the second conductive type semiconductor layer is a p-type semiconductor layer or a p-type emitter layer in the case of the n-type silicon substrate.

A groove may be defined by a ditch and may indicate a ditch that penetrates through the second conductive type semiconductor layer and reaches a predetermined depth on the upper portion of the first conductive type semiconductor substrate. The groove may be formed in a line dug to a predetermined depth when viewing from above the solar cell.

In the present invention, the groove may be formed by an edge isolation process to isolate a front surface and a rear surface of the first conductive type semiconductor substrate.

The edge isolation process is known in the art and is not particularly limited. Preferably, the edge isolation process may be any one of a laser isolation method, a plasma etching method, and an etchant etching method.

In the present invention, the groove may be formed in a line type ditch and may be located in any places suitable to isolate the front surface and the rear surface of the first conductive type semiconductor substrate. Preferably, the groove may be formed at an edge of the solar cell.

In the present invention, the rear surface of the substrate may further be provided with a rear electric field layer electrically connected to the second electrode. In this case, the rear electric field layer is stacked on the rear surface of the first conductive type semiconductor substrate and the second electrode is formed on a predetermined place, and may be formed so as to contact a portion of the first conductive type semiconductor substrate.

Further, according to one embodiment of the present invention, the surfaces of the first conductive type semiconductor substrate, the second conductive type semiconductor layer, and an anti-reflective layer may be an unevenness structure.

The unevenness structure may be formed by forming the surface of the first conductive type semiconductor substrate uneven through a texturing method and sequentially stacking thin film layers thereon.

In the present invention, the anti-reflective layer may be made of one or more material selected from the group consisting of silicon nitride (SiNₓ), silicon oxide (SiO₂), and intrinsic amorphous silicon, but is not particularly limited thereto. Also, the thickness of the anti-reflective layer may be several tens to several hundreds nanometers, preferably, 10 nm to 900 nm.

In the present invention, since the position where the anti-reflective layer, the first electrode, and the second electrode are formed is not particularly limited, the solar cell according to the present invention may be applied to an IBC type or an MWT type (Metal-Wrap-Through type).

The method for manufacturing a solar cell according to one embodiment of the present invention may further comprise a step of forming the rear field layer on the rear surface of the substrate before, during, or after forming the first and second electrodes.

In other words, the rear field layer that can be formed on the rear surface of the first conductive type semiconductor substrate may first be formed followed by forming the first electrode and the second electrode and may be formed together during forming these electrodes. Also, the rear electric field layer may be formed on the rear surface of the remaining substrate other than a position where the second electrode is formed, not a type where all the electrodes are formed and the second electrode is then covered thereon.

In the present invention, the step of forming the second conductive type semiconductor layer may be formed by doping second conductive type semiconductor impurities having a conductive type opposite to the first conductive type on the first conductive type semiconductor substrate. Therefore, if the first conductive type semiconductor substrate is a p-type semiconductor substrate, the impurities are one or more material selected from the group consisting of Group V elements that are n-type semiconductor impurities and if the substrate is an n-type substrate, as the impurities, materials selected from the group consisting of Group III elements that are p-type semiconductor impurities may be used.

The present invention may further comprise a step of texturing the surface of the first conductive type semiconductor substrate, prior to the step of forming the second conductive type semiconductor layer.

Also, the present invention may further comprise a step of removing an insulating layer generated during forming the second conductive type semiconductor layer. The insulating layer is not limited to any particular materials. Meanwhile, as by-products generated at the time of forming the second conductive type semiconductor layer, by-product layers of glasses such as phosphosilicate glass (PSG) or borosilicate glass (BSG) may representatively be generated. In the present invention, a process of removing the by-products may be performed in any steps after the step of performing the edge isolation but preferably, may be performed between a step of removing a damaged layer and a step of forming an anti-reflective layer.

In the present invention, the edge isolation at the step of performing the edge isolation may be formed by any one of a laser edge isolation method, a plasma etching method, and an etchant etching method.

In the manufacturing method according to the present invention, the anti-reflective layer may be made of one or more material selected from the group consisting of silicon nitride (SiNₓ), silicon oxide (SiO₂), and intrinsic amorphous silicon. Also, the thickness of the anti-reflective layer is several tens to several hundreds of nanometers based on a bottom surface of the groove, preferably, 10 nm to 900 nm.

Hereinafter, preferred embodiments of the present invention will be described with reference to the accompanying drawings.

Configuration of Solar Cell

FIG. 1 is a cross-sectional view showing a configuration of a silicon solar cell according to one embodiment of the present invention.

As shown in FIG. 1, a silicon solar cell 300 of the present invention includes first conductive type semiconductor substrates sequentially formed, specifically, at least a first conductive type silicon substrate 310, a second conductive type semiconductor layer or an emitter layer 320, and an anti-reflective layer 350, wherein the anti-reflective layer 350 penetrates through the second conductive type emitter layer 320 from an edge of the first conductive type silicon substrate 310 according to a structure formed by a laser edge isolation process and contacts the first conductive type silicon substrate 310.

The first conductive type and the second conductive type may respectively be a p-type and an n-type or vice versa. Herein, for convenience of explanation, a case where the first conductive type and the second conductive type is respectively a p-type and an n-type will be described by way of example.

In manufacturing the silicon solar cell, among several methods used for forming a p-n junction, a method of forming the n-type emitter layer 320 by doping n-type materials on the p-type silicon substrate 310 is widely used. When the method is used, doping materials can be doped even on an edge portion of the silicon substrate 310 in the doping process. Thereby, the front and rear surfaces of the silicon substrate 310 are electrically connected to each other, which may be a cause of reducing the efficiency of the solar cell.

Therefore, the edge isolation process should be performed without exception in order to isolate the front and rear surfaces or the upper and lower surfaces of the silicon substrate 310. The laser edge isolation process is one of such edge isolation processes.

The present invention performs the laser edge isolation after forming the n-type emitter layer 320 and forms the anti-reflective layer 350 after removing a damaged layer 330 generated by a laser, such that the anti-reflective layer 350 performing a function of a passivation layer and a function of a double anti-reflective layer covers the surface subjected to the laser edge isolation process.

In other words, the present invention has a structure that the anti-reflective layer 350 penetrates through the n-type emitter layer 320 from the edge portion of the silicon substrate 310 and contacts the p-type silicon substrate 310. Since a groove formed from the n-type emitter layer 320 to a predetermined depth of the p-type silicon substrate 310 is formed at the edge portion of the silicon substrate 310 before applying the anti-reflective layer 350, the penetration can be made only by applying the anti-reflective layer 350 and as described above, wherein the groove is generated from the result of the laser edge isolation process.

The defects and recombination of electrons-holes in the vicinity of the surface are minimized by the structure where the anti-reflective layer 350 covers the surface subjected to the laser edge isolation, thereby making it possible to improve the efficiency and reliability of the solar cell.

The anti-reflective layer 350 may be made of materials such as silicon nitride (SiNₓ), silicon oxide (SiO₂), and intrinsic amorphous silicon. This can perform a function of minimizing reflectance of the solar cell 300 as well as a function as a passivation layer. Meanwhile, the anti-reflective layer 350 may be formed at a proper thickness in consideration of an effect as the passivation layer and a function as the double anti-reflective layer, preferably, several tens to several hundreds nanometers (nm). The anti-reflective layer 350 may be formed of two layers or more in consideration of the above-mentioned functions.

Hereinafter, the manufacturing process of the solar cell 300 having the above-mentioned structure and a structure that can be formed by any principle will be described in detail.

Method of Manufacturing Solar Cell

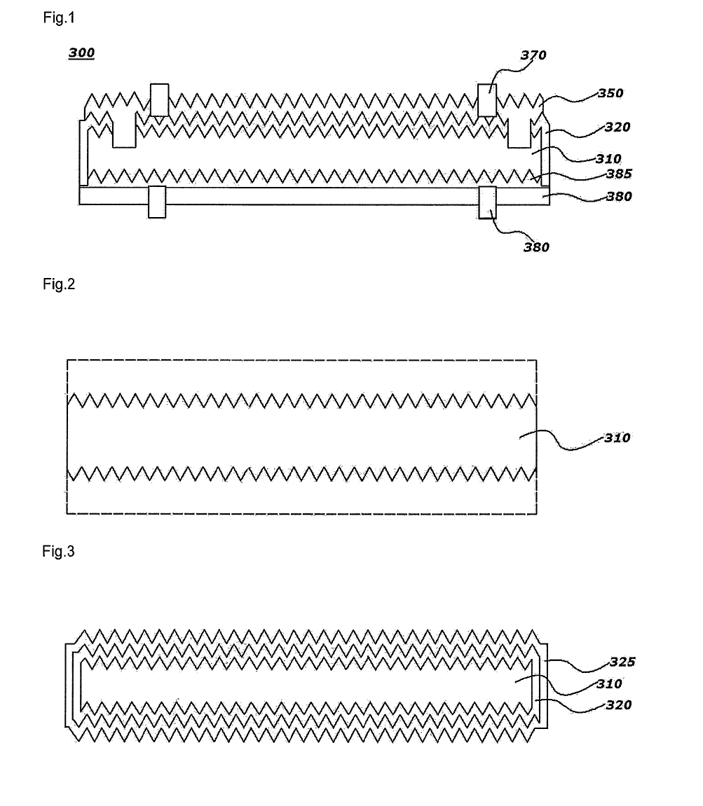

FIGS. 2 to 8 are diagrams sequentially showing processes of manufacturing the silicon solar cell 300 according to one embodiment of the present invention. Hereinafter, the processes of manufacturing the silicon solar cell 300 will be described with reference to FIGS. 2 to 8.

First, as shown in FIG. 2, a texturing structure is formed on at least one surface of the upper surface or the lower surface of the p-type silicon substrate 310. The texturing structure diffusedly reflects sunlight incident to the inside of the solar cell 300, such that it performs a function of lowering reflectance of the sunlight and collecting light. As a method of forming the texturing structure, a process of dipping the p-type crystalline silicon substrate 310 into etchant, etc can be used and the texturing structure can be formed in various shapes, such as a pyramid shape, a regular squared honeycomb shape, a triangular honeycomb shape.

Next, as shown in FIG. 3, in order to form the p-n junction, the n-type emitter layer 320 is formed on the p-type silicon substrate 310. The n-type emitter layer 320 may be formed by methods, such as a diffusion method, a spray method, or a printing process method, but it is assumed that the present invention uses the diffusion method.

As one example, the n-type emitter layer 320 may be formed by injecting the n-type materials (for example, phosphorus (P) that is penta-valent) into the p-type silicon substrate 310.

As a method of diffusing the n-type materials, a thermal diffusion method, etc., can be used. As one example, a method of putting the p-type silicon substrate 310 in a high-temperature furnace, injecting the n-type materials (for example, POCl₃) into the inside of the furnace, and doping them can be used. On the other hand, the n-type emitter layer 320 may be formed by directly injecting the n-type materials into the p-type silicon substrate 310 using an ion implantation method. At this time, the emitter layer 320 may of course be formed as an n⁺-type by relatively increasing the concentration of the injected n-type material.

In order to form the n-type emitter layer 320, since the doping material is doped on the edge portion of the silicon substrate 310 in a process of doping the n-type material, the front and rear surfaces of the silicon substrate 310 are electrically connected to each other, which may be a cause of reducing the efficiency of the solar cell. Therefore, the edge isolation process should be performed without exception in order to isolate the front and rear surfaces or the upper and lower surfaces of the silicon substrate 310. FIG. 4 shows an appearance after isolating the front and rear surfaces of the silicon substrate by the laser edge isolation that is one of the isolation processes.

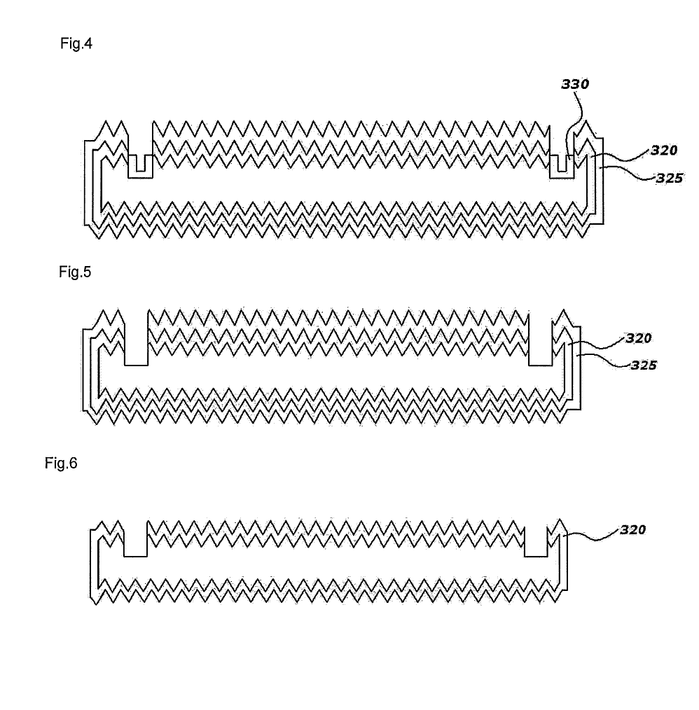

When the laser edge isolation process is performed, a portion melted by a high-temperature laser and then hardened, that is, the damaged layer 330 may be formed. Since this may be a cause of degrading the efficiency of the solar cell, this should be removed. To this end, the damaged layer 330 can be controlled by using base solutions such as potassium hydroxide (KOH) solution or sodium hydroxide (NaOH). FIG. 5 shows an appearance after removing the damaged layer 330 by using these base solutions.

Meanwhile, in the process of diffusing the n-type materials in order to form the n-type emitter layer 320, by-product layers or insulation layers 325 of glasses such as phosphosilicate glass (PSG) or borosilicate glass (BSG) may be formed on the surface of the silicon substrate 310.

After the laser edge isolation process is performed and the damaged layer 330 generated by this process is removed, the insulation layer 325 of PSG or BSG, etc., is removed. This removal may be performed by known technologies such as a wet etching method using a hydrofluoric acid (HF) solution. FIG. 6 shows an appearance after the insulating layer 325 is removed.

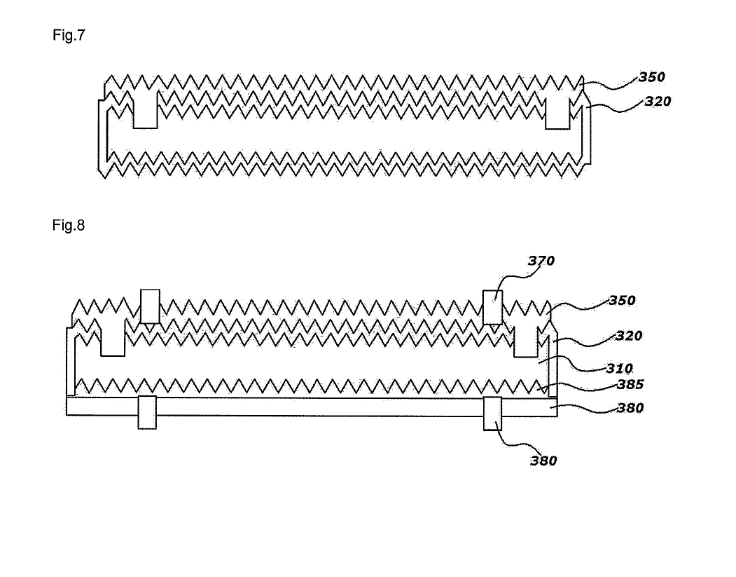

After the insulating layer 325 is removed, as shown in FIG. 7, the anti-reflective layer 350 is formed on the n-type emitter layer 320. The anti-reflective layer 350 may be deposited by using a chemical vapor deposition method and may use materials such as silicon nitride (SiNₓ), silicon oxide (SiO₂), or intrinsic amorphous silicon. This anti-reflective layer 350 can perform a function of minimizing reflectance of the solar cell 300 as well as a function as the passivation layer. As a result, the defects of the solar cell 300 are minimized and the recombination of pairs of electrons-holes is reduced, making it possible to improve the efficiency of the solar cell 300. The anti-reflective layer 350 may be formed at a thickness of several tens to several hundreds nanometers in consideration of the function as the passivation layer and the double anti-reflective layer. The anti-reflective layer 350 may be formed of two layers or more in consideration of the above-mentioned functions.

In the present invention, since the damaged layer 330 generated after the laser edge isolation process is removed and then, the anti-reflective layer 350 serving as the passivation layer and the double anti-reflective layer are formed, the anti-reflective layer 350 is applied on the surface subjected to the edge isolation process, such that the surface subjected to the edge isolation process can be protected by the anti-reflective layer 350.

Thereby, the surface of the edge isolation is not exposed to air and the surface thereof is not formed with unnecessary oxide, etc., such that the recombination of electrons-holes, etc., can be prevented, making it possible to improve the efficiency of the solar cell.

The subsequent processes are the same as the method of manufacturing the solar cell in the related art. Briefly describing, after forming the anti-reflective layer 350, as shown in FIG. 8, first and second electrodes 370 and 380 are formed and a rear field forming layer 385 is formed by performing heat treatment.

The first electrode 370 may be formed by using materials such as silver Ag. As a forming method, a screen printing method, etc., can be used and the first electrode 370 penetrates through the anti-reflective layer 350 and electrically contacts the n-type emitter layer 320 by application of the heat treating process later.

On the other hand, the second electrode 380 may be formed by using materials such as aluminum (Al) and may also be formed using the screen printing method, etc. After the first electrode 370 and the second electrode 380 are printed, if they are heat-treated at high temperature, the second electrode 380 serves as an impurity at the lower surface of the silicon substrate 310 to change the lower surface of the substrate 310 into a p⁺-type or a p⁺⁺-type. The p⁺-type layer or the p⁺⁺-type layer serve as the field forming layer 385. The field forming layer 385 minimizes the rear recombination of electrons generated by sunlight, making it possible to improve the efficiency of the solar cell.

Although the diffused silicon solar cell was described as one embodiment of the present invention, the present invention can be applied to a thin film type and/or a hybrid type, that is, a solar cell of a type having a p/i/n junction structure by forming an amorphous silicon layer on a semiconductor substrate, etc.

Although the present invention has been described in detail with reference to its presently preferred embodiment, it will be understood by those skilled in the art that various modifications and equivalents can be made without departing from the spirit and scope of the present invention, as set forth in the appended claims.

Thus, it is intended that the present invention covers the modifications and variations of this invention provided they come within the scope of the appended claims and their equivalents.

What is claimed is:

1. A solar cell, comprising:
a first conductive type semiconductor substrate;
a second conductive type semiconductor layer that is formed on the substrate and has a conductive type opposite to the first conductive type;
at least one groove that penetrates through the second conductive type semiconductor layer and reaches a predetermined depth of the first conductive type semiconductor substrate;
a protective layer formed on the groove;
a first electrode that electrically contacts the second conductive type semiconductor layer; and
a second electrode that is formed on the first conductive type semiconductor substrate.

2. The solar cell according to claim 1, wherein the groove is formed at an edge of the solar cell.

3. The solar cell according to claim 1, wherein the groove is an edge isolation region to isolate front and rear surfaces of the first conductive type semiconductor substrate.

4. The solar cell according to claim 1, wherein the rear surface of the substrate is further provided with a rear electric field layer beside the second electrode.

5. The solar cell according to claim 1, wherein the surface of the first conductive type semiconductor substrate has an unevenness structure.

6. The solar cell according to claim 1, wherein the second conductive type semiconductor layer is formed on the front surface of the semiconductor substrate and the second electrode is formed on the rear surface of the semiconductor substrate.

7. The solar cell according to claim 1, wherein the second conductive type semiconductor layer and the second electrode are formed on the rear surface of the semiconductor substrate.

8. The solar cell according to claim 1, wherein an anti-reflective layer is formed on the second conductive type semiconductor layer.

9. The solar cell according to claim 8, wherein the anti-reflective layer is made of one or more material selected from a group consisting of silicon nitride (SiNₓ), silicon oxide (SiO₂), and intrinsic amorphous silicon.

10. The solar cell according to claim 8, wherein the thickness of the anti-reflective layer is 10 nm to 900 nm.

11. The solar cell according to claim 8, wherein the anti-reflective layer is formed of two layers or more.

12. The solar cell according to claim 8, wherein the anti-reflective layer is made of the same material as the protective layer.

13. The solar cell according to claim 8, wherein the anti-reflective layer is connected to the protective layer.

14. A method of manufacturing a solar cell, comprising:
forming a first conductive type semiconductor layer;
forming a second conductive type semiconductor layer having a conductive type opposite to the first conductive type on a first conductive type semiconductor substrate;
performing edge isolation to isolate front and rear surfaces of the first conductive type semiconductor substrate;
removing a damaged layer formed by the edge isolation;
burying a groove formed by removing the damaged layer and forming an anti-reflective layer applied on the second conductive type semiconductor layer; and
forming a first electrode that contacts at least a portion of the second conductive type semiconductor layer and the anti-reflective layer, and a second electrode that contacts at least a portion of the rear surface of the substrate.

15. The method according to claim 14, further comprising the step of forming the rear electric field layer on the rear surface of the substrate before, during, or after forming the first and second electrodes.

16. The method according to claim 14, wherein the step of forming the second conductive type semiconductor layer is performed by doping a second conductive type semiconductor impurity having a conductive type opposite to the first conductive type on the first conductive type semiconductor substrate.

17. The method according to claim 14, further comprising the step of texturing the surface of the first conductive type semiconductor substrate, prior to forming the first and second electrodes.

18. The method according to claim 14, further comprising the step of removing an insulating layer generated in the process of forming the second conductive type semiconductor layer, prior to forming the anti-reflective layer.

19. The method according to claim 14, wherein the edge isolation includes any one of a laser edge isolation method, a plasma etching method, and an etchant etching method.

20. The method according to claim 14, wherein the anti-reflective layer is made of one or more material selected from the group consisting of silicon nitride (SiNₓ), silicon oxide (SiO₂), and intrinsic amorphous silicon.

21. The method according to claim 14, wherein the thickness of the anti-reflective layer is 10 nm to 900 nm.

22. The method according to claim 14, wherein the anti-reflective layer is formed of two layers or more.

23. The method according to claim 14, wherein the step of forming the first electrode includes forming an electrode on the anti-reflective layer, performing heat treatment thereon, and contacting it on the second conductive type semiconductor layer.
